(19) United States
(12) Patent Application Publication
(10) Pub. No.: US 2013/0181192 A1
(43) Pub. Date: Jul. 18, 2013

(54) ORGANIC FLOATING GATE MEMORY DEVICE HAVING PROTEIN AND METHOD OF FABRICATING THE SAME

(71) Applicants: Jenn-Chang HWANG, Hsinchu (TW); Li Shiuan TSAI, Hsinchu (TW); Jon-Yiew GAN, Hsinchu (TW)

(72) Inventors: Jenn-Chang HWANG, Hsinchu (TW); Li Shiuan TSAI, Hsinchu (TW); Jon-Yiew GAN, Hsinchu (TW)

(21) Appl. No.: 13/572,997

(22) Filed: Aug. 13, 2012

(30) Foreign Application Priority Data
Jan. 12, 2012 (TW) 101101236

(51) Int. Cl. H01L 51/30; H01L 51/40

(52) U.S. Cl. 257/40; 438/99; 257/E51.025; 257/E51.006

(57) ABSTRACT

An organic floating gate memory device having protein and a method of fabricating the same are disclosed. The organic floating gate memory device of the present invention comprises: a substrate; a gate electrode on the substrate; a gate dielectric layer covering the gate electrode; a floating gate on the gate dielectric layer; a protein dielectric layer covering the floating gate; and an organic semiconductor layer, a source and a drain, wherein the organic semiconductor layer, the source and the drain are disposed over the protein dielectric layer

### BACKGROUND OF THE INVENTION

1. Field of the Invention

The present invention relates to an organic floating gate memory device having protein and a method of fabricating the same, and particularly to an organic floating gate memory device using protein as a dielectric layer and a method of fabricating the same.

2. Description of Related Art

With the rapid development of technology, electronic products such as mobile phones, notebook computers, tablet personal computers, flash drives, and digital cameras have become our daily necessity. Memory devices, which play an important role in these electronic products, can be generally classified into volatile memory and non-volatile memory. Volatile memory refers to that computer memory for which the storage data in it will disappear with the removal of the external power supply. Examples of volatile memory include static random access memory, and dynamic random access memory. Non-volatile memory refers to the kind for which storage data in the memory will not disappear with the removal of the external power supply, and can be stored for a long time. Examples of non-volatile memory include read-only memory, programmable read-only memory, erasable programmable read-only memory, electric erasable programmable read-only memory, and flash memory. Furthermore, non-volatile memory is mainly characterized as a charge-trapping device and a floating gate device by its structure.

Generally, an organic floating gate memory device has advantages of being light and cheap when compared to a conventional silicon-based floating gate memory device. FIG. 1 shows a typical organic floating gate memory device, which includes a substrate 11; a gate electrode 12 on the substrate 11; a gate dielectric layer 13 covering the gate electrode 12; a floating gate 14 on the gate dielectric layer 13; a floating gate dielectric layer 15 covering the floating gate 14; and an organic semiconductor layer 16, a source 17 and a drain 18, disposed over the floating gate dielectric layer 15. There are many common dielectric materials such as SiO₂, AlN, TiO₂, and Si₃N₄.

In addition, when a common dielectric material is to be formed for the gate dielectric or insulating layer in an organic floating gate memory device, it is required to use sputtering or vacuum deposition equipment, which substantially increases the production costs and process complexity.

Therefore, a current demand in the art is to develop a dielectric material for an organic floating gate memory device that has properties of being light and cheap, as well as being applicable in a flexible electronic product.

### SUMMARY OF THE INVENTION

An object of the present invention is to provide an organic floating gate memory device having protein comprising a substrate; a gate electrode locating on the substrate; a gate dielectric layer covering the gate electrode; a floating gate on the gate dielectric layer; a protein dielectric layer covering the floating gate; and an organic semiconductor layer, a source and a drain, wherein the organic semiconductor layer, the source and the drain are disposed over the protein dielectric layer.

In the present invention, the organic floating gate memory device using a bioprotein as the dielectric material has properties of being flexible, light, cheap, and environmental friendly. As such, it can be employed in an organic electronic product, to achieve the objects of light-weight, low-cost, and improved portability.

Bioprotein can be considered as an excellent dielectric material for the flexible electronic product due to its flexible nature and low cost. Bioprotein is hereby used as the floating gate dielectric layer in the invention, on which an organic semiconductor layer is coated to form the floating gate memory device. Such a device has a great potential in the industry, and provides important advances in the flexible electronic products.

In the organic floating gate memory device having protein of the present invention, the substrate may be a plastic substrate, a paper substrate, a glass substrate, a quartz substrate, or a silicon substrate, and preferably a plastic substrate or a paper substrate, to form a flexible device.

In the organic floating gate memory device having protein of the present invention, the material of the organic semiconductor layer may be pentacene, carbon-60, N,N′-dioctyl-3,4,9,10-perylenedicarboximide (PTCDI-C8), or perfluoropentacene.

In the organic floating gate memory device having protein of the present invention, the protein dielectric layer has a bioprotein which is modified or non-modified, and the bioprotein is a silk protein. The protein dielectric layer serves as the tunneling layer in the floating gate memory device, and carriers in the semiconductor layer may penetrate to the floating gate electrode under the effect of vertical electric field. After the vertical electric field is removed, carriers are stored in the floating agate, completing the writing process.

In the organic floating gate memory device having protein of the present invention, the material of the gate dielectric layer may be any kind of dielectric materials, comprising organic dielectric materials, or inorganic dielectric materials, and preferably a silk protein. A bioprotein is advantageously used to increase the flexibility of the organic floating gate memory device.

The organic floating gate memory device having protein of the present invention has a threshold voltage shift of preferably 0.8V to 1.8V after a program voltage is applied. That is, the value difference between the threshold voltages before and after applying a program voltage to the organic floating gate memory device is 1V to 2 V. In the organic floating gate memory device having protein of the present invention, the organic floating gate memory device has a program voltage of preferably −5V to −45V.

In the organic floating gate memory device having protein of the present invention, the organic floating gate memory device has an erase voltage of preferably 5V to 45V.

The organic floating gate memory device having protein of the present invention may preferably be a flexible organic floating gate memory device.

In the organic floating gate memory device having protein of the present invention, when the organic floating gate memory device is a top contact organic Boating gate memory device, the organic semiconductor layer is disposed over the protein dielectric layer, and the source and the drain are disposed over the organic semiconductor layer.

In the organic floating gate memory device having protein of the present invention, when the organic floating gate memory device is a bottom-contact organic floating gate memory device, the source and the drain is disposed over the protein dielectric layer, and the organic semiconductor layer covers the source, the drain, and a portion of the protein dielectric layer.

In the organic floating gate memory device having protein of the present invention, the material of the floating gate is selected from the group consisting of: aluminum, copper, nickel, magnesium, calcium, lithium, chromium, silver, platinum, gold, zinc oxide (ZnO), indium tin oxide (ITO), zinc indium oxide (IZO), zinc aluminum oxide (AZO), indium gallium zinc oxide (IGZO), hafnium oxide (HfO2), and mixtures thereof.

Furthermore, the present invention also provides a method for fabricating an organic floating gate memory device having protein, which comprises the following steps: (A) providing a substrate; (B) forming a gate electrode on the substrate; (C) forming a gate dielectric layer covering the gate electrode; (D) forming a floating gate on the gate dielectric layer; (E) forming a protein dielectric layer covering the floating gate; and (F) forming an organic semiconductor layer, a source, and a drain over the protein dielectric layer, wherein the material of the protein dielectric layer is a silk protein. φ

In the method for fabricating the organic floating gate memory device having protein of the present invention, a silk protein is used to form a dielectric layer comprising a bioprotein on the floating gate electrode. In contrasts to the conventional method for forming the gate dielectric layer by vacuum sputtering, vacuum evaporation, or chemical vapor deposition (CVD), the method of the present invention employs a solution process to obtain the organic floating gate memory device having protein, which is simple, low cost, and particularly suitable for large area coating and mass production.

In the method for fabricating the organic floating gate memory device having protein of the present invention, the substrate may be a plastic substrate, a paper substrate, a glass substrate, a quartz substrate, or a silicon substrate, and preferably a plastic substrate or a paper substrate, to form a flexible device.

In the method for fabricating the organic floating gate memory device having protein of the present invention, the material of the organic semiconductor layer may be pentacene, carbon-60, N,N′-dioctyl-3,4,9,10-perylenedicarboximide (PTCDI-C8), or perfluoropentacene.

In the method for fabricating the organic floating gate memory device having protein of the present invention, the protein dielectric layer has a bioprotein which is modified or non-modified, and the bioprotein is a silk protein. In the method for fabricating the organic floating gate memory device having protein of the present invention, the material of the gate dielectric layer may be any kind of dielectric materials, and preferably a silk protein.

In the method for fabricating the organic floating gate memory device having protein of the present invention, the organic floating gate memory device having protein has an threshold voltage shift of preferably 0.8V to 1.8V after a program voltage is applied. That is, the value difference between the threshold voltages before and after applying a program voltage to the organic floating gate memory device is 1V to 2 V. In the method for fabricating the organic floating gate memory device having protein of the present invention, the organic floating gate memory device has a program voltage of preferably −5V to −45V.

In the method for fabricating the organic floating gate memory device having protein of the present invention, the organic floating gate memory device has an erase voltage of preferably 5V to 45V.

In the method for fabricating the organic floating gate memory device having protein of the present invention, the organic floating gate memory device having protein of the present invention may be preferably a flexible organic floating gate memory device.

In the method for fabricating the organic floating gate memory device having protein of the present invention, the material of the floating gate is selected from the group consisting of: aluminum, copper, nickel, magnesium, calcium, lithium, chromium, silver, platinum, gold, zinc oxide (ZnO), indium tin oxide (ITO), zinc indium oxide (IZO), zinc aluminum oxide (AZO), indium gallium zinc oxide (IGZO), hafnium oxide (HfO2), and mixtures thereof.

In the method for fabricating the organic floating gate memory device having protein of the present invention, wherein in step (F), when the organic floating gate memory device is a top-contact organic floating gate memory device, the organic semiconductor layer covers the protein dielectric layer, and the source and the drain are disposed over the organic semiconductor layer.

In the method for fabricating the organic floating gate memory device having protein of the present invention, wherein in step (F), when the organic floating gate memory device is a bottom-contact organic floating gate memory device, the source and the drain is disposed over the protein dielectric layer, and the organic semiconductor layer covers the source, the drain, and a portion of the protein dielectric layer.

### BRIEF DESCRIPTION OF THE DRAWINGS

FIG. 1 shows a schematic view of a conventional organic floating gate memory device.

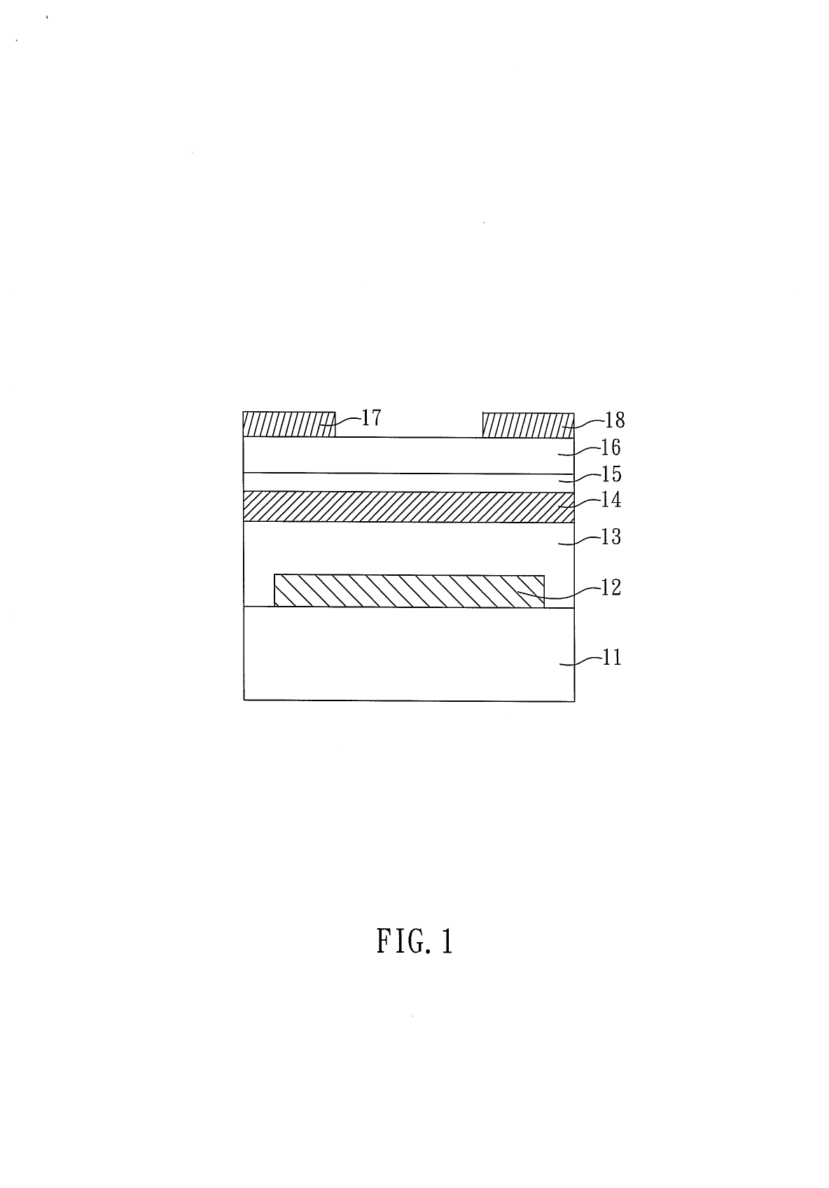

FIG. 2 shows a schematic cross-section of a top-contact organic floating gate memory device having a protein material of Example 1.

FIG. 3 shows the transfer characteristics test of the top-contact organic floating gate memory device having a protein material of Example 1 under a negative bias.

FIG. 4 shows schematic cross-section of the bottom-contact organic floating gate memory device having a protein material of Example 2.

### DETAILED DESCRIPTION OF THE PREFERRED EMBODIMENT

In the following description, numerous specific details are set forth to provide a thorough understanding of embodiments of the present disclosure.

However, one having an ordinary skill in the art will recognize that embodiments of the disclosure can be practiced without these specific details. In some instances, well-known structures and processes are not described in detail to avoid unnecessarily obscuring embodiments of the present disclosure.

### EXAMPLE 1

### Top-Contact Organic Floating Gate Memory Device Having A Protein Material

### Preparation of Silk Solution

First, an aqueous 10 wt % sodium carbonate solution is prepared and heated to boil. The solution is further boiled for 30 minutes to 1 hour to remove the sericin in the outer layer of silk after addition of dried silkworm cocoon (natural silk). Then, the silk is washed by deionized water to remove the alkaline solution on the outer layer of silk. After drying, a refined silk protein, namely, fibroin, is obtained.

Next, the refined silk protein is placed, stirred, and dissolved in a 20 ml of 85 wt % H3PO4 solution. After that, the H3PO4 solution containing dissolved silk protein is placed in a dialysis membrane (Spectra/Por 3 dialysis membrane, molecular weight cutoff=14000) and dialyzed with water for 3 days, to remove the excess phosphate. By controlling the water volume and the dialysis frequency, not only the phosphate can be removed, but also the pH value of the obtained silk solution can be adjusted. Here, the pH value of the obtained silk solution is maintained at 2˜6. After the dialysis process was finished, the impurity is removed using a filter paper to obtain the silk solution.

### Preparation of Top-Contact Organic Floating Gate Memory Device Having A Protein Material

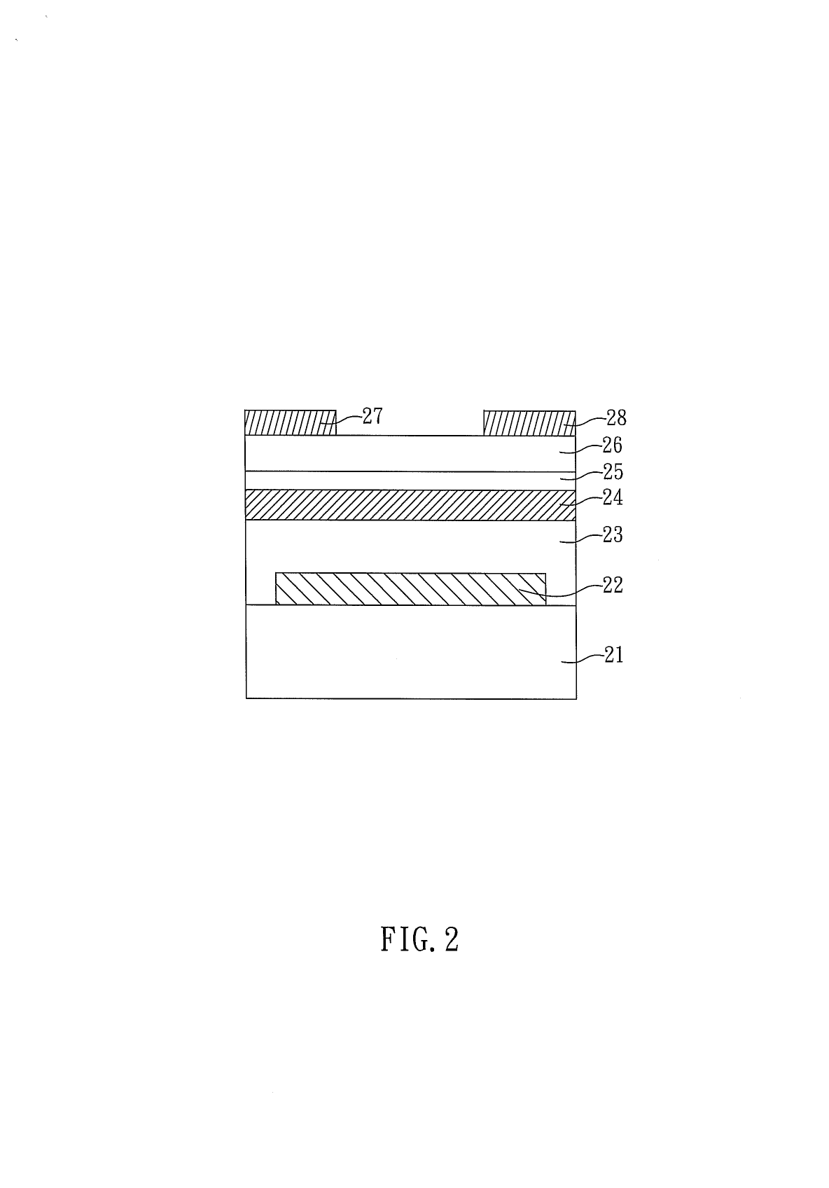

First, as referenced in FIG. 2, a substrate 21 is provided and washed with deionized water by ultrasonication. In this Example, the substrate 21 is a transparent PET plastic substrate.

Then, the substrate 21 is placed in a vacuum chamber (not shown), and, a mask (not shown) is used to form a patterned metal layer as a gate electrode 22 on the substrate 21 by evaporation coating. In this Example, the material of the gate electrode 22 is gold, and has a thickness of 80 nm. The conditions for forming the gate electrode 22 by thermal evaporation coating are illustrated as follows:

Vacuum degree: 5×10⁻⁶ torr

Deposition rate: 1 Å/s

Next, the substrate 21 with the gate electrode 22 formed thereon is immersed in the above silk solution for 15 minutes so as to coat the silk solution on the substrate 21. After that, the silk solution coated on the substrate 21 is dried at a temperature of 60° C., to form a silk film serving as a gate dielectric layer 23. In this Example, the gate dielectric layer 23 formed from the silk film has a thickness of 400 nm. In addition, the procedures of coating the silk solution and drying could be optionally repeated for several times to form a multilayer silk structure.

Afterwards, a mask is used to form a patterned metal layer, serving as a floating gate electrode 2, on the gate dielectric layer 23 by evaporation coating, wherein the material of the floating gate electrode 24 is gold. The substrate 21 with the gate electrode 22 and the floating gate electrode 24 formed thereon is dipped in the above silk solution for 15 minutes so as to coat the silk solution on the floating gate electrode 24 to form a biopolymer protein film serving as a protein dielectric layer 25.

Then, a shadow metal mask is used to deposit pentacene, serving as an organic semiconductor layer 26, on the protein dielectric layer 25 at room temperature (about 25° C.) by thermal evaporation coating. In this Example, the organic semiconductor layer 26 has a thickness of 60 nm. The conditions for forming the organic semiconductor layer 26 by thermal evaporation coating are illustrated as follows:

Vacuum degree: 3×10⁻⁶ torr

Deposition rate: 0.3 Å/s

Finally, another mask (not shown) is used to form a patterned metal layer on the organic semiconductor layer 26 by evaporation coating through the same process conditions as for forming the gate electrode, and the patterned metal layer served as a source 27 and a drain 28. In this Example, the material of the source 27 and the drain 28 is gold, and has a thickness of 70 nm.

Through the above-mentioned processes, the top-contact organic floating gate memory device having a protein material of this Example is obtained, including: a substrate 21; a gate electrode 22 on the substrate 21; a gate dielectric layer 23 covering the gate electrode 22; a floating gate 24 on the gate dielectric layer 23; a protein dielectric layer 25 covering the floating gate 24; and an organic semiconductor layer 26, a source 27 and a drain 28, disposed over the protein dielectric layer 25.

### Characteristics Evaluation

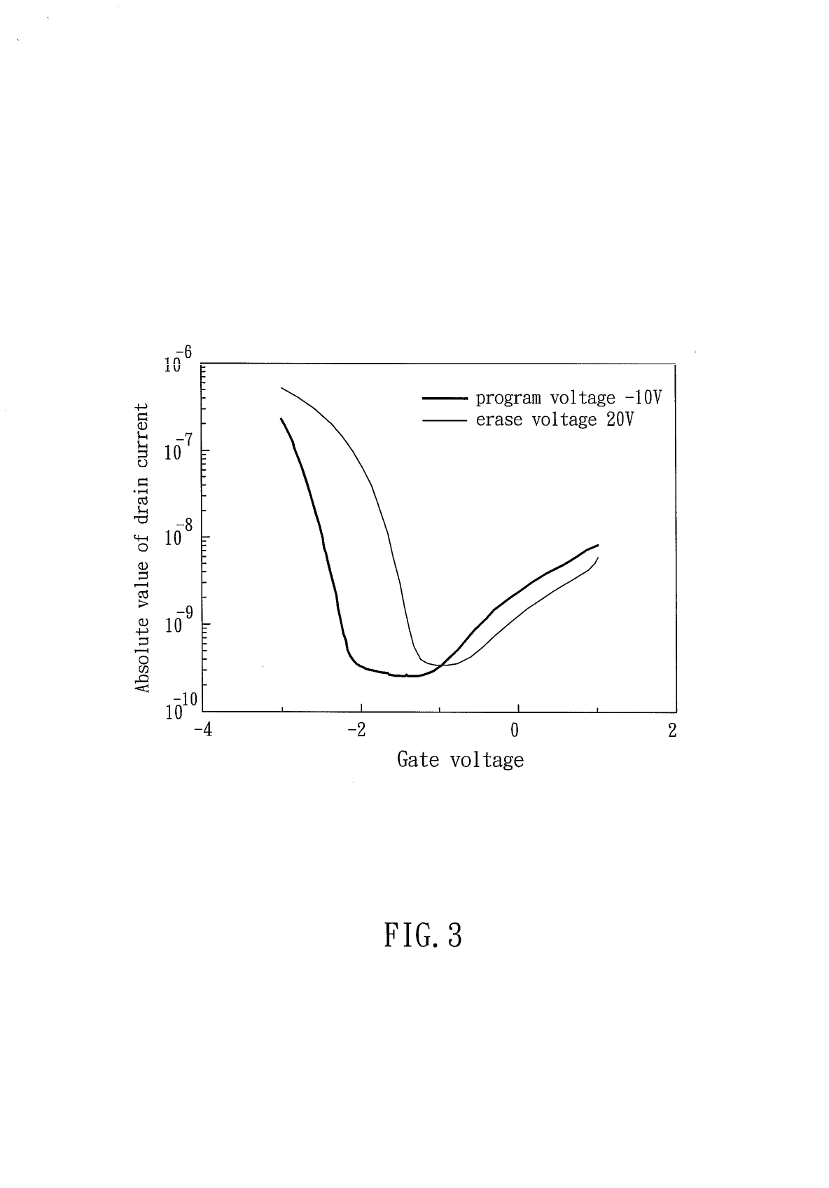

Current-voltage test is performed on the top-contact organic floating gate memory device having a protein material of Example 1 and the result of transfer characteristics is shown in FIG. 3. After the organic floating gate memory device having a silk protein is applied with a program voltage of −10V, the threshold voltage shifts 1V towards the negative region due to accumulation of charges in the floating gate. After an erase voltage of 20V is applied, the accumulated charges at the floating gate electrode are released, and the threshold voltage shifts towards the positive region. This confirms that the top-contact organic floating gate memory device can store charges and provides a memory function.

The top-contact organic floating gate memory device having a protein material has many advantages, including that the pentacene organic semiconductor layer has great air stability, flexibility, low process temperature, and high hole mobility, as well as being environmentally friendly. In addition, silk materials are cheaper and match well with each other, and therefore the top-contact organic floating gate memory device has a great economic value.

### EXAMPLE 2

### Bottom-Contact Organic Floating Gate Memory Device Having A Protein Material

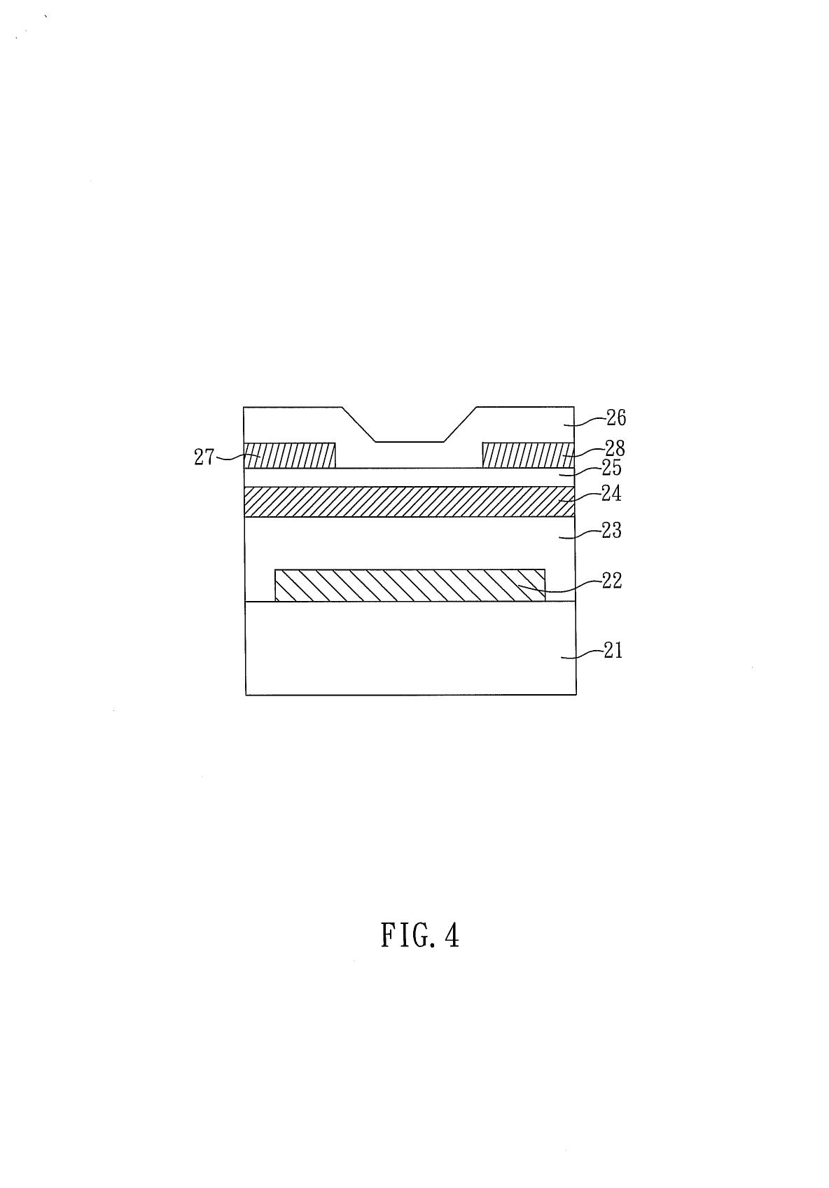

Referring to FIG. 4, a substrate 21 is provided, and gate electrode 22 and gate dielectric layer 23 are formed thereon sequentially. In this Example, the same method for manufacturing the substrate 21, gate electrode 22, and gate dielectric layer 23 as in Example 1 is performed. In this Example, the gate electrode has a thickness of 80 nm, and the gate dielectric layer 23 has a thickness of 400 nm.

Then, a mask (not shown) is used to form a patterned metal layer on the gate dielectric layer 23 by evaporation coating, to form a floating gate electrode 24 made of gold. By the same method as in Example 1, a biopolymer protein film is formed on the floating gate electrode 24 to serve as the protein dielectric layer 25.

Through the same process conditions for forming the gate electrode as in Example 1, a patterned metal layer is formed on the protein dielectric layer 25 by evaporation coating, to serve as a source 27 and a drain 28. In this Example, the material of the source 27 and the drain 28 is gold, and has a thickness of 70 nm.

Finally, through the same process conditions as in Example 1, the organic semiconductor layer 26 is formed on the protein dielectric layer 25, the source 27, and the drain 28. In this Example 2, the material of the organic semiconductor layer 26 is pentacene, and has a thickness of 70 nm.

Through the above-mentioned processes, the bottom-contact organic floating gate memory device having a protein material in the Example 2 is obtained, comprising: a substrate 21; a gate electrode 22 on the substrate 21; a gate dielectric layer 23 covering the gate electrode 22; a floating gate 24 on the gate dielectric layer 23; a protein dielectric layer 25 covering the floating gate 24; a source 27 and a drain 28, disposed over the protein dielectric layer 25; and an organic semiconductor layer 26, covering the protein dielectric layer 25, the source 27, and the drain 28.

While the disclosure has described by way of example and in terms of the preferred embodiments, it is to be understood that the disclosure is not limited to the disclosed embodiments. The scope of the appended claims should be accorded the broadest interpretation so as to encompass all such modifications and similar arrangements.

What is claimed is:

1. An organic floating gate memory device having protein, comprising:
a substrate;
a gate electrode on the substrate;
a gate dielectric layer covering the gate electrode;
a floating gate on the gate dielectric layer;
a protein dielectric layer covering the floating gate; and
an organic semiconductor layer, a source and a drain, wherein the organic semiconductor layer, the source and the drain are disposed over the protein dielectric layer.

2. The organic floating gate memory device having protein of claim 1, wherein a material of the organic semiconductor layer is pentacene, carbon-60, N,N′-dioctyl-3,4,9,10-perylenedicarboximide (PTCDI-C8), or perfluoropentacene.

3. The organic floating gate memory device having protein of claim 1, wherein the protein dielectric layer has a bioprotein which is modified or non-modified, and the bioprotein is a silk protein.

4. The organic floating gate memory device having protein of claim 1, wherein a material of the gate dielectric layer comprises an organic dielectric material, an inorganic dielectric material, or a bioprotein comprising a silk protein.

5. The organic floating gate memory device having protein of claim 1, having a threshold voltage shift of 0.8V to 1.8V after a program voltage is applied.

6. The organic floating gate memory device having protein of claim 1, wherein the organic floating gate memory device has a program voltage of −5V to −45V.

7. The organic floating gate memory device having protein of claim 1, wherein the organic floating gate memory device has an erase voltage of 5V to 45V.

8. The organic floating gate memory device having protein of claim 1, wherein the organic floating gate memory device is a flexible organic floating gate memory device.

9. The organic floating gate memory device having protein of claim 1, wherein the organic floating gate memory device is a top-contact organic floating gate memory device, and the organic semiconductor layer covers the protein dielectric layer, and the source and the drain are disposed over the organic semiconductor layer.

10. The organic floating gate memory device having protein of claim 1, wherein the organic floating gate memory device is a bottom-contact organic floating gate memory device, and the source and the drain is disposed over the protein dielectric layer, and the organic semiconductor layer covers the source, the drain, and a portion of the protein dielectric layer.

11. The organic floating gate memory device having protein of claim 1, wherein a material of the floating gate is selected from the group consisting of: aluminum, copper, nickel, magnesium, calcium, lithium, chromium, silver, platinum, gold, zinc oxide (ZnO), indium tin oxide (ITO), zinc indium oxide (IZO), zinc aluminum oxide (AZO), indium gallium zinc oxide (IGZO), hafnium oxide (HfO2), and mixtures thereof.

12. The organic floating gate memory device having protein of claim 1, wherein the substrate is a plastic substrate, a paper substrate, a glass substrate, a quartz substrate, or a silicon substrate.

13. A method for fabricating an organic floating gate memory device having protein, comprising the following steps:
(A) providing a substrate;
(B) forming a gate electrode on the substrate;
(C) forming a gate dielectric layer covering the gate electrode;
(D) forming a floating gate on the gate dielectric layer;
(E) forming a protein dielectric layer covering the floating gate; and
(F) forming an organic semiconductor layer, a source, and a drain over the protein dielectric layer.

14. The method for fabricating an organic floating gate memory device having protein of claim 13, wherein a material of the organic semiconductor layer is pentacene, carbon-60, N,N′-dioctyl-3,4,9,10-perylenedicarboximide (PTCDI-C8), or perfluoropentacene.

15. The method for fabricating an organic floating gate memory device having protein of claim 13, wherein the protein dielectric layer has a bioprotein which is modified or non-modified, and the bioprotein is a silk protein.

16. The method for fabricating an organic floating gate memory device having protein of claim 13, wherein a material of the gate dielectric layer comprises an organic dielectric material, an inorganic dielectric material, or a bioprotein comprising a silk protein.

17. The method for fabricating an organic floating gate memory device having protein of claim 13, wherein the organic floating gate memory device has a threshold voltage shift of 0.8V to 1.8V after a program voltage is applied.

18. The method for fabricating an organic floating gate memory device having protein of claim 13, wherein the organic floating gate memory device has a program voltage of −5V to −45V.

19. The method for fabricating an organic floating gate memory device having protein of claim 13, wherein the organic floating gate memory device has an erase voltage of 5V to 45.

20. The method for fabricating an organic floating gate memory device having protein of claim 13, wherein the organic floating gate memory device is a flexible organic floating gate memory device.

21. The method for fabricating an organic floating gate memory device having protein of claim 13, wherein a material of the floating gate is selected from the group consisting of: aluminum, copper, nickel, magnesium, calcium, lithium, chromium, silver, platinum, gold, zinc oxide (ZnO), indium tin oxide (ITO), zinc indium oxide (IZO), zinc aluminum oxide (AZO), indium gallium zinc oxide (IGZO), hafnium oxide (HfO2), and mixtures thereof.

22. The method for fabricating an organic floating gate memory device having protein of claim 13, wherein, in the step (F), the organic floating gate memory device is a top-contact organic floating gate memory device, and the organic semiconductor layer covers the protein dielectric layer, and the source and the drain are disposed over the organic semiconductor layer.

23. The method for fabricating an organic floating gate memory device having protein of claim 13, wherein, in the step (F), the organic floating gate memory device is a bottom-contact organic floating gate memory device, and the source and the drain is disposed over the protein dielectric layer, and the organic semiconductor layer covers the source, the drain, and a portion of the protein dielectric layer.

24. The method for fabricating an organic floating gate memory device having protein of claim 13, wherein the substrate is a plastic substrate, a paper substrate, a glass substrate, a quartz substrate, or a silicon substrate.
